(19) United States
(12) Patent Application Publication
(10) Pub. No.: US 2024/0244815 A1
(43) Pub. Date: Jul. 18, 2024

(54) COMPONENT MOUNTER AND ELECTRONIC COMPONENT IMAGING METHOD

(71) Applicant: FUJI CORPORATION, Chiryu (JP)

(72) Inventor: Shota SHIMIZU, Toyota-shi (JP)

(73) Assignee: FUJI CORPORATION, Chiryu (JP)

(21) Appl. No.: 18/558,980

(22) PCT Filed: Jun. 7, 2021
(86) PCT No.: PCT/JP2021/021641

§ 371 Date: Nov. 3, 2023

(51) Int. Cl. H05K 13/08; H05K 13/04

(52) U.S. Cl. CPC H05K 13/0812; H05K 13/0408; H05K 13/0413; H05K 13/046

(57) ABSTRACT

A component includes a board conveyance device, a component supply device, a nozzle, a component moving device, an imaging device, and a control device to, in a case where the electronic component picked up by the nozzle has an enough size to be disposed over both the entire imaging range of the imaging device and a space above the board conveyed to the work position, when the electronic component is imaged by the imaging device, cause the component moving device to rotate the nozzle at a position at which the electronic component is not located in the space above the board and cause the imaging device to image the electronic component from below before and after the nozzle is rotated about the axis.

### TECHNICAL FIELD

The present description relates to a component mounter for mounting an electronic component on a board and an electronic component imaging method.

### BACKGROUND ART

In a component mounter for mounting an electronic component on a board, the electronic component may be picked up by a nozzle, the electronic component may be moved to a predetermined position on the board, and the electronic component may be mounted on the board. Such a component mounter includes an imaging device that images the electronic component picked up by the nozzle from below in order to confirm a loss or a defect of the electronic component picked up by the nozzle or to confirm a deviation of a posture when the electronic component is picked up by the nozzle. In a case where the electronic component is large, the entire imaging target region of the electronic component may not fit within an imaging range of the imaging device. In such a case, the imaging is executed multiple times while moving the electronic component to the imaging device, and the entire imaging target region of the electronic component is imaged. For example, JP-A-H10-267619 discloses a component mounter that, in a case where an electronic component is large, rotates the electronic component to image the entire desired range of the electronic component.

### SUMMARY OF THE INVENTION

### Technical Problem

In the component mounter disclosed in JP-A-H10-267619, in a case where the electronic component is large, the electronic component is rotated, and the electronic component is imaged from below. However, depending on a size or a shape of the electronic component, a portion of the electronic component may be located in a space above the board when the electronic component is imaged. When the electronic component is located in the space above the board when the electronic component is imaged, the electronic component may interfere with an electronic component previously mounted on the board.

The present description discloses a technique for avoiding interference between a large electronic component and another electronic component previously mounted on a board when the large electronic component is imaged from below.

### Solution to Problem

The present description discloses a component mounter for mounting an electronic component on a board. The component mounter includes a board conveyance device configured to convey the board to a work position in the component mounter, a component supply device configured to supply the electronic component, a nozzle configured to pick up the electronic component supplied from the component supply device, a component moving device that is capable of moving the nozzle between the component supply device and the work position and rotating the nozzle about an axis of the nozzle, an imaging device disposed between the component supply device and the board conveyance device and configured to image the electronic component, which is picked up by the nozzle, from below, and a control device configured to, in a case where the electronic component picked up by the nozzle has an enough size to be disposed over both the entire imaging range of the imaging device and a space above the board conveyed to the work position, when the electronic component is imaged by the imaging device, cause the component moving device to rotate the nozzle at a position at which the electronic component is not located in the space above the board and cause the imaging device to image the electronic component from below before and after the nozzle is rotated about the axis.

Further, the present description discloses a component mounter for mounting an electronic component on a board. The component mounter includes a board conveyance device configured to convey the board to a work position in the component mounter, a component supply device configured to supply the electronic component, a nozzle configured to pick up the electronic component supplied from the component supply device, a component moving device that is capable of moving the nozzle between the component supply device and the work position and rotating the nozzle about an axis of the nozzle, an imaging device disposed between the component supply device and the board conveyance device and configured to image the electronic component, which is picked up by the nozzle, from below, and a control device configured to, in a case where the electronic component picked up by the nozzle interferes with an electronic component previously mounted on the board conveyed to the work position when the nozzle is translated in a plane parallel to a surface of the board such that the electronic component picked up by the nozzle is disposed in the entire imaging range of the imaging device, when the electronic component picked up by the nozzle is imaged by the imaging device, cause the component moving device to rotate the nozzle at a position at which the electronic component picked up by the nozzle does not interfere with the previously mounted electronic component and cause the imaging device to image the electronic component, which is picked up by the nozzle, from below before and after the nozzle is rotated about the axis.

In the component mounter, when the electronic component is imaged from below, a position at which the electronic component is rotated is determined according to a size of the electronic component. Accordingly, when a large electronic component is imaged from below, the interference between the electronic component and another electronic component previously mounted on the board can be avoided.

Further, the present description discloses an imaging method of, when an electronic component supplied from an electronic component supply position is mounted on a board disposed at a work position, imaging the electronic component, which is disposed in an imaging range provided between the electronic component supply position and the board, from below in the imaging range. The imaging method includes a determination step of determining whether the electronic component has an enough size to be disposed over both the entire imaging range and a space above the board, and an imaging step of imaging the electronic component from below when it is determined in the determination step that the electronic component has an enough size to be disposed over both the entire imaging range and the space above the board, in which the electronic component is rotated at a position at which the electronic component is not located in the space above the board and the electronic component is imaged from below before and after the rotation.

Also in the imaging method, since the position at which the electronic component is rotated is determined according to the size of the electronic component when the electronic component is imaged from below, the interference with another electronic component previously mounted on the board can be avoided.

### BRIEF DESCRIPTION OF DRAWINGS

FIG. 1 is a view illustrating a schematic configuration of a component mounter according to an example.

FIG. 2 is a cross-sectional view taken along line II-II of FIG. 1.

FIG. 3 is a block diagram illustrating a control system of the component mounter according to the example.

FIG. 4 is a flowchart illustrating an example of processing of imaging a lower surface of an electronic component, which is picked up by a nozzle, by an imaging device.

FIG. 5 is a view illustrating a positional relationship between the electronic component and a circuit board when the electronic component having an enough size to be disposed over both the entire imaging range of the imaging device and a space above the circuit board is imaged, in which (a) illustrates a state in which the electronic component is not located in the space above the circuit board and (b) illustrates a state in which the electronic component is located in the space above the circuit board.

FIG. 6 is a flowchart illustrating an example of processing of imaging the electronic component having a size disposed over the entire imaging range of the imaging device and the space above the circuit board.

FIG. 7 is a view illustrating an example of the imaging processing of FIG. 6, and illustrates a state in which imaging region 1 is located in the imaging range.

FIG. 8 is a view illustrating an example of the imaging processing of FIG. 6, and illustrates a state in which imaging region 9 is located in the imaging range.

FIG. 9 is a view illustrating an example of the imaging processing of FIG. 6, and illustrates a state in which the electronic component is rotated by 90 degrees from the state of FIG. 8.

FIG. 10 is a view illustrating an example of the imaging processing of FIG. 6, and illustrates a state in which imaging region 14 is located in the imaging range.

FIG. 11 is a view illustrating an example of the imaging processing of FIG. 6, and illustrates a state in which the electronic component is rotated by 90 degrees from the state of FIG. 10.

### DESCRIPTION OF EMBODIMENTS

Main features of an example described below are listed. Technical elements described below are technical elements independent of each other, exhibit technical usefulness alone or in various combinations, and are not limited to combinations described in claims at the time of filing.

In the component mounter disclosed in the present description, in a case where the electronic component is large (specifically, in a case where the electronic component has a size to be located also in the space above the board when the electronic component is moved in the space above the imaging device in order to image the electronic component by the imaging device), the control device rotates the nozzle such that the electronic component is not located in the space above the board, and images the electronic component before and after the nozzle is rotated. Accordingly, when the electronic component is imaged by the imaging device, the electronic component is avoided from being located in the space above the board. Therefore, when the electronic component is imaged, the interference of the imaged electronic component with an electronic component previously mounted on the board can be avoided.

In the component mounter disclosed in the present description, the imaging device may be configured to, in a case where the electronic component picked up by the nozzle has an enough size to be disposed over both the entire imaging range of the imaging device and the space above the board conveyed to the work position, image each of multiple imaging regions obtained by dividing an imaging target region of the electronic component. The control device may be configured to cause the component moving device to execute translation processing of translating the nozzle in a plane parallel to a surface of the board at the position at which the electronic component is not located in the space above the board, and rotation processing of rotating the nozzle about the axis at the position at which the electronic component is not located in the space above the board. The control device may be configured to cause the imaging device to image all the multiple imaging regions by combining the translation processing and the rotation processing. With such a configuration, in a case where the electronic component is large, the entire electronic component can be suitably imaged.

In addition, the imaging method disclosed in the present description may further include a division step of dividing an imaging target region of the electronic component into multiple imaging regions when it is determined in the determination step that the electronic component has an enough size to be disposed over both the entire imaging range and the space above the board disposed at the work position. The imaging step may include a translation step of translating the electronic component in a plane parallel to a surface of the board at the position at which the electronic component is not located in the space above the board, and a rotation step of rotating the electronic component in the plane parallel to the surface of the board at the position at which the electronic component is not located in the space above the board. In the imaging step, all the multiple imaging regions may be imaged by combining the translation step and the rotation step. Even with such a configuration, in a case where the electronic component is large, the entire electronic component can be suitably imaged.

### EXAMPLE

Component mounter 10 according to the example will be described with reference to the drawings. Component mounter 10 is a device that mounts electronic component 4 on circuit board 2. Component mounter 10 is also referred to as an electronic component mounting device or a chip mounter. Normally, component mounter 10 is provided together with other board work machines, such as a solder printing machine and a board inspection machine, to form a series of mounting lines.

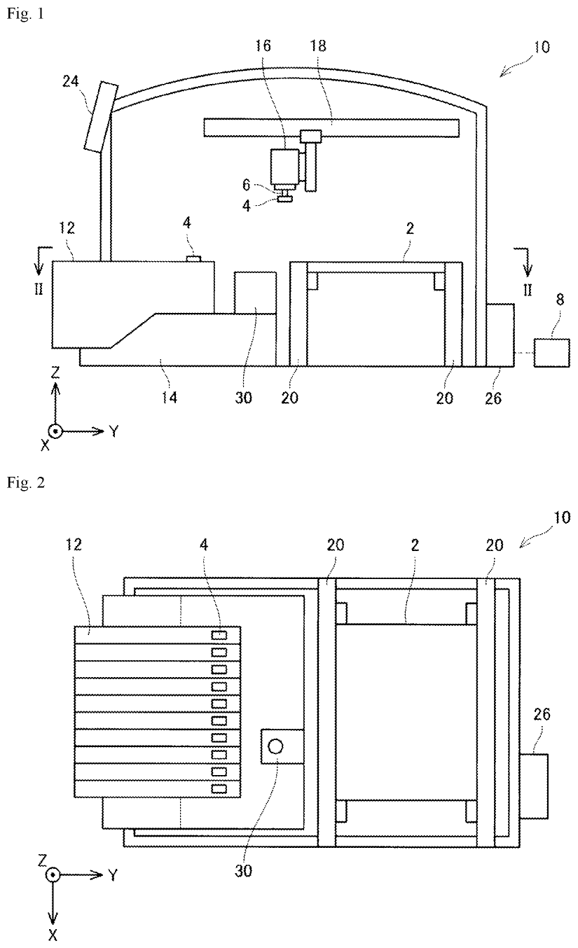

As illustrated in FIGS. 1 and 2, component mounter 10 includes multiple component feeders 12, feeder holding section 14, mounting head 16, head moving device 18, board conveyor 20, imaging device 30, control device 26, and touch panel 24. Management device 8 that is capable of communicating with component mounter 10 is disposed outside component mounter 10.

Each component feeder 12 accommodates multiple electronic components 4. Component feeder 12 is detachably attached to feeder holding section 14 and supplies electronic component 4 to mounting head 16. A specific configuration of component feeder 12 is not particularly limited. Each component feeder 12 may be, for example, any of a tape type feeder that supplies multiple electronic components 4 accommodated on a tape, a tray type feeder that supplies multiple electronic components 4 accommodated on a tray, and a bulk type feeder that supplies multiple electronic components 4 randomly accommodated in a container.

Feeder holding section 14 includes multiple slots, and component feeder 12 can be detachably installed in each of the multiple slots. Feeder holding section 14 may be fixed to component mounter 10 or may be detachable from component mounter 10.

Mounting head 16 includes nozzle 6 that picks up electronic component 4. Nozzle 6 is detachably attached to mounting head 16. Mounting head 16 can move nozzle 6 in a Z direction (vertical direction here) and moves nozzle 6 towards and away from component feeder 12 or circuit board 2. Mounting head 16 can rotate nozzle 6 about an axis (axis extending in the Z direction) of nozzle 6. Mounting head 16 can pick up electronic component 4 from component feeder 12 by nozzle 6 and can mount electronic component 4 picked up by nozzle 6 on circuit board 2. When mounting head 16 rotates nozzle 6 about the axis, electronic component 4 is rotated on a plane (XY plane) orthogonal to the axis of nozzle 6. Mounting head 16 is not limited to the mounting head having single nozzle 6 but may be a mounting head having multiple nozzles 6.

Head moving device 18 moves mounting head 16 between component feeder 12 and circuit board 2. As an example, head moving device 18 of the present example is an XY robot that moves moving base 18a in an X direction and a Y direction, and mounting head 16 is fixed to moving base 18a. Head moving device 18 can translate nozzle 6 on the plane (XY plane) parallel to the surface of circuit board 2. Mounting head 16 is not limited to the mounting head fixed to moving base 18a but may be a mounting head detachably attached to moving base 18a.

Board conveyor 20 is a device that conveys in, positions, and conveys out circuit board 2. As an example, board conveyor 20 of the present example includes a pair of belt conveyors and a supporting device (not illustrated) that supports circuit board 2 from below.

Imaging device 30 is disposed between component feeder 12 and board conveyor 20 (in more detail, board conveyor 20 installed on a side facing component feeders 12 in pair of board conveyors 20). Imaging device 30 includes a camera and a light source. The camera is disposed such that an imaging direction of the camera is upward, and images nozzle 6 in a state of picking up electronic component 4, from below. That is, when nozzle 6 picks up electronic component 4, the camera images a lower surface of electronic component 4 picked up by nozzle 6. For example, a CCD camera is used as the camera. The light source is configured of an LED and illuminates the lower surface (imaging surface) of electronic component 4 picked up by nozzle 6. Image data of an image captured by imaging device 30 is stored in a memory (not illustrated) of control device 26.

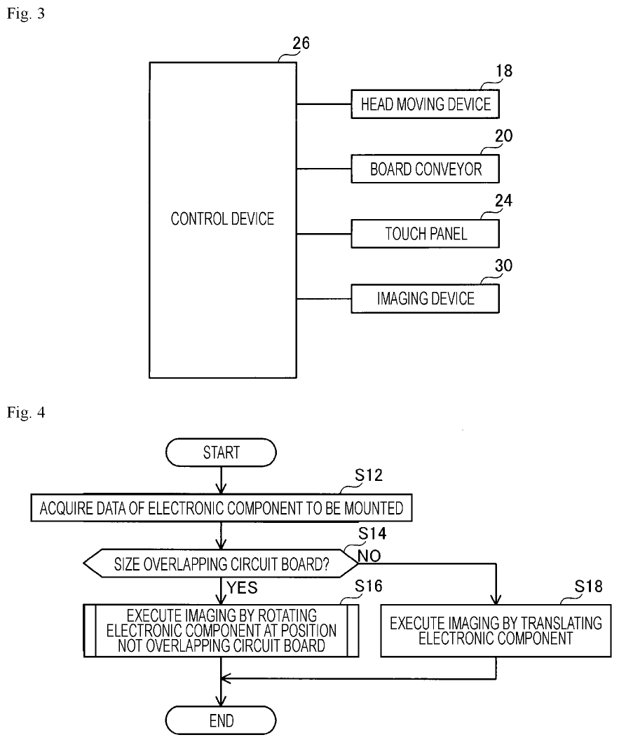

Control device 26 is configured of a computer including CPU and a storage device. Control device 26 controls an operation of each section of component mounter 10 based on a production program transmitted from management device 8. As illustrated in FIG. 3, control device 26 is connected to head moving device 18, board conveyor 20, touch panel 24, and imaging device 30, and controls each section of head moving device 18, board conveyor 20, touch panel 24, and imaging device 30. Touch panel 24 is a display device that provides an operator with various information on component mounter 10, as well as an input device that receives instructions or information from the operator.

Next, processing of imaging the lower surface of electronic component 4, which is picked up by nozzle 6, by imaging device 30 will be described. When electronic component 4 is mounted on circuit board 2, the lower surface of electronic component 4 is imaged by imaging device 30 in a state in which electronic component 4 supplied from component feeder 12 is picked up by nozzle 6. From the captured image, it is confirmed that there is no loss or defect in electronic component 4 or that a posture of electronic component 4 picked up to nozzle 6 is not deviated. When it is confirmed from the captured image that electronic component 4 has no problem, electronic component 4 is mounted on circuit board 2. When an imaging target region on the lower surface of electronic component 4 is larger than an imaging range of imaging device 30, the imaging is executed by dividing the imaging target region into multiple imaging regions. When each imaging region is imaged, a position of electronic component 4 in a height direction is adjusted such that imaging device 30 is focused on the imaging region is in focus of, and electronic component 4 is moved such that the imaging region fits within the imaging range of imaging device 30. In this case, when a portion of electronic component 4 is located in the space above circuit board 2, electronic component 4 may interfere with electronic component 4 previously mounted on circuit board 2. Hereinafter, processing of imaging electronic component 4 such that imaged electronic component 4 does not interfere with another electronic component 4 previously mounted on circuit board 2 will be described. In the present example, a case where the entire lower surface of electronic component 4 is imaged will be described as an example. The range (imaging target region) imaged by imaging device 30 may be a desired portion of the range of the lower surface of electronic component 4.

As illustrated in FIG. 4, first, control device 26 acquires data related to electronic component 4 mounted on circuit board 2 (S12). The data related to electronic component 4 is stored in the memory (not illustrated) of control device 26. The data related to electronic component 4 includes information related to a shape or a size of electronic component 4. Control device 26 acquires the data related to electronic component 4 from the memory.

Next, based on the data related to electronic component 4 acquired in step S12, control device 26 determines whether electronic component 4 has a size that overlaps the space above circuit board 2 when electronic component 4 is imaged by imaging device 30 (S14). When electronic component 4 is imaged by imaging device 30, electronic component 4 is imaged at a predetermined height in the space above imaging device 30. The predetermined height is a height at which imaging device 30 is focused. In the present example, since a depth of field of imaging device 30 is shallow, a distance from imaging device 30 to electronic component 4 (that is, a predetermined height of electronic component 4) is set to be constant. In a case where the imaging target region (entire lower surface in the present example) of electronic component 4 is larger than the imaging range of imaging device 30, the imaging target region is divided into the multiple imaging regions. Then, electronic component 4 is moved at the predetermined height, and all the multiple imaging regions are imaged.

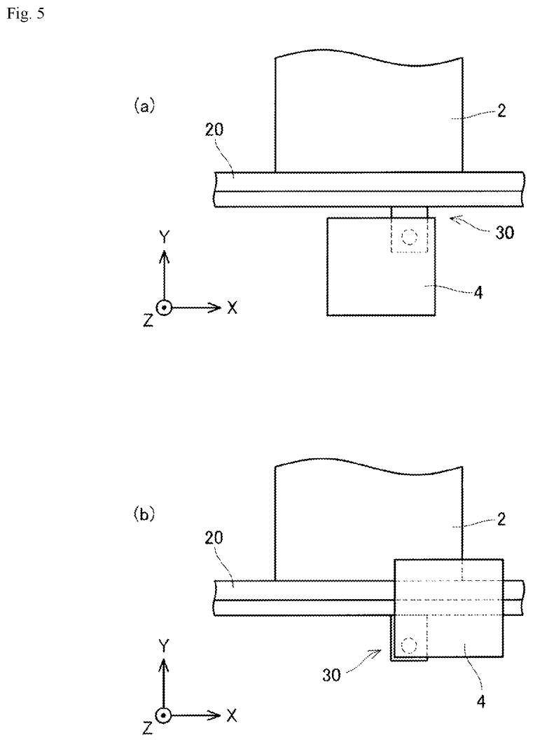

In a case where electronic component 4 is large, a portion of electronic component 4 may be located in the space above circuit board 2 when electronic component 4 is moved at the predetermined height such that the imaging target region of electronic component 4 fits within the imaging range of imaging device 30. That is, in a case where electronic component 4 is large, when electronic component 4 is moved at the predetermined height such that the imaging target region of electronic component 4 fits within the imaging range of imaging device 30, electronic component 4 may be located not to be located in the space above circuit board 2 as illustrated in (a) of FIG. 5, and a portion of electronic component 4 may also be located in the space above circuit board 2 as illustrated in (b) of FIG. 5. When electronic component 4 is moved at the predetermined height, control device 26 determines whether electronic component 4 may be located over both the imaging range of imaging device 30 and circuit board 2 (whether electronic component 4 has an enough size to be disposed at a position illustrated in (b) of FIG. 5). For example, control device 26 determines whether a dimension of electronic component 4 in the Y direction exceeds a set value ((b) of FIG. 5).

In a case where electronic component 4 has the size disposed over both the imaging range of imaging device 30 and circuit board 2 (YES in step S14), control device 26 rotates nozzle 6 in the axial direction at a position at which electronic component 4 does not overlap circuit board 2, and images the entire imaging target region (S16). For example, by rotating nozzle 6 such that electronic component 4 is rotated at the position illustrated in (a) of FIG. 5, the entire imaging target region is imaged such that electronic component 4 is not disposed at the position illustrated in (b) of FIG. 5.

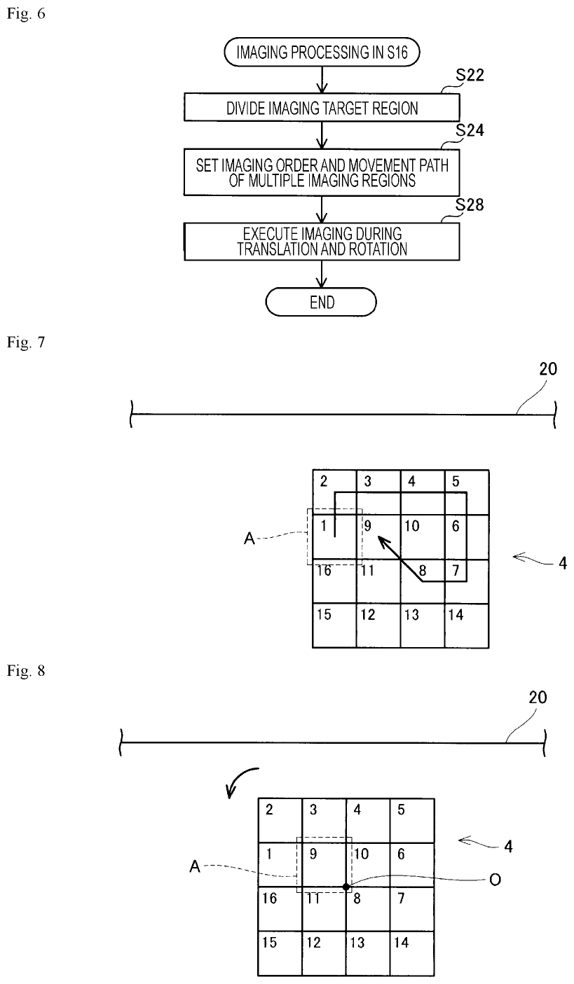

The more specific description will be made with reference to FIG. 6. As illustrated in FIG. 6, in the processing of imaging the imaging target region in step S16, first, control device 26 divides the imaging target region of electronic component 4 (S22). Then, multiple imaging regions are generated. As will be described below, in the present example, one image is generated by combining multiple images obtained by imaging the multiple imaging regions. Therefore, each imaging region is set to be smaller than the imaging range of imaging device 30.

Next, control device 26 sets an imaging order and a movement path of the multiple imaging regions such that all the multiple imaging regions are imaged (S24). When the movement path is set, translation of moving nozzle 6 (that is, electronic component 4 picked up by nozzle 6) in the plane (XY plane) parallel to the surface of circuit board 2 and rotation of rotating nozzle 6 (that is, electronic component 4 picked up by nozzle 6) about the axis of nozzle 6 are combined. In this case, both the translation and the rotation are set to be executed at a position at which electronic component 4 is not located in the space above circuit board 2.

Thereafter, control device 26 images the multiple imaging regions in the imaging order set in step S24 while moving electronic component 4 along the movement path set in step S24 (S28).

An example of the processing (processing of FIG. 6) of imaging the imaging target region in step S16 will be described with reference to FIGS. 7 to 11. In step S14 (see FIG. 4), when control device 26 determines that electronic component 4 has the size disposed over both the imaging range of imaging device 30 and circuit board 2 (YES in step S14), control device 26 divides the imaging target region of electronic component 4 in step S22 (see FIG. 6). Control device 26 divides the imaging target region of electronic component 4 such that the entire one divided imaging region fits within imaging range A of imaging device 30. In the present example, the entire lower surface of electronic component 4 is imaged. In the example illustrated in FIG. 7, control device 26 divides the entire lower surface of electronic component 4 into 16 imaging regions. Imaging range A of imaging device 30 includes the entire divided imaging region and a portion of peripheral regions. For example, in FIG. 7, electronic component 4 is disposed at a position at which the center of imaging range A coincides with the center of imaging region 1. In this case, imaging range A includes entire imaging region 1, a portion of imaging regions 2, 3, 9, 11, and 16, and a portion outside electronic component 4 (portion on a left side of imaging region 1 in FIG. 7). After imaging all the imaging regions, all the imaging regions are combined to generate the image of the imaging target region (entire lower surface of electronic component 4 in the present example). When a portion the peripheral regions of each imaging region is included in the image obtained by imaging each imaging region, an overlapping portion is generated between adjacent imaging regions. By imaging the imaging regions in this manner, the imaging regions can be accurately combined.

In the examples illustrated in FIGS. 7 to 11, electronic component 4 does not overlap circuit board 2 (for example, the state of (a) of FIG. 5) even when electronic component 4 is translated such that the imaging regions of three rows on the side of board conveyor 20 (three regions respectively extending from imaging regions 2, 1, and 16 in a horizontal direction in FIG. 7) are located in imaging range A of imaging device 30, and electronic component 4 overlaps circuit board 2 (for example, the state of (b) of FIG. 5) when electronic component 4 is translated such that the imaging region in one row away from board conveyor 20 (one region extending from imaging region 15 in the horizontal direction in FIG. 7) is located in imaging range A of imaging device 30.

Next, control device 26 sets the imaging order and the movement path of the multiple imaging regions in step S24 (see FIG. 6), and control device 26 images each imaging region while moving electronic component 4 in accordance with the set imaging order and movement path in step S26 (see FIG. 6).

For example, FIG. 7 illustrates the imaging order of the imaging regions to which the numbers in the imaging regions are set. First, control device 26 translates nozzle 6 such that the center of imaging region 1 coincides with the center of imaging range A (state illustrated in FIG. 7). Control device 26 images electronic component 4 at that position. Then, entire imaging region 1 is imaged. Next, control device 26 translates nozzle 6 such that the center of imaging region 2 coincides with the center of imaging range A, and images entire imaging region 2. Similarly, control device 26 translates nozzle 6 and subsequently images imaging regions 3 to 9. As described above, in the example illustrated in FIG. 7, electronic component 4 does not overlap circuit board 2 even when electronic component 4 is translated such that the imaging regions of three rows on the side of board conveyor 20 are located in imaging range A of imaging device 30. Therefore, in imaging regions 1 to 9 located in three rows on the side of board conveyor 20 in FIG. 7, the imaging is executed while electronic component 4 is translated. When electronic component 4 is translated such that imaging region 9 is imaged, electronic component 4 is located at the position illustrated in FIG. 8.

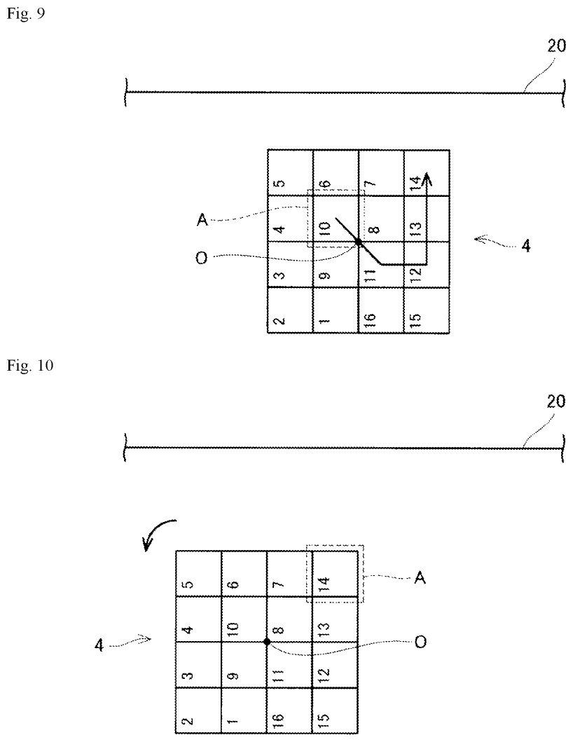

When imaging region 9 is imaged, control device 26 rotates nozzle 6 about the axis of nozzle 6 counterclockwise by 90 degrees. When nozzle 6 picks up electronic component 4, nozzle 6 picks up electronic component 4 at a position at which the axis of nozzle 6 substantially coincides with center O of electronic component 4. In the following description, it is assumed that the axis of nozzle 6 coincides with center O of electronic component 4. When nozzle 6 is rotated about the axis of nozzle 6, electronic component 4 is rotated about center O. In the example illustrated in FIG. 8, imaging region 9 is located in the second row from the side of board conveyor 20. Therefore, even when electronic component 4 is rotated about center O of electronic component 4 in the state illustrated in FIG. 8, electronic component 4 (particularly, a right corner portion of imaging region 5 in the state illustrated in FIG. 8) does not overlap circuit board 2. When electronic component 4 is rotated by 90 degrees about the axis of nozzle 6, electronic component 4 is changed from the state illustrated in FIG. 8 to the state illustrated in FIG. 9. In this case, imaging region 10 is located in imaging range A. Therefore, after the rotation, control device 26 images imaging region 10 without translating electronic component 4.

Thereafter, control device 26 translates nozzle 6 and images each of imaging regions 11 to 14. Since imaging regions 11 to 14 are located in the first to third rows on the side of board conveyor 20 in the state illustrated in FIG. 9, even when electronic component 4 is translated for the imaging of imaging regions 10 to 14, electronic component 4 does not overlap circuit board 2. When electronic component 4 is translated such that imaging region 14 is imaged, electronic component 4 is located at the position illustrated in FIG. 10.

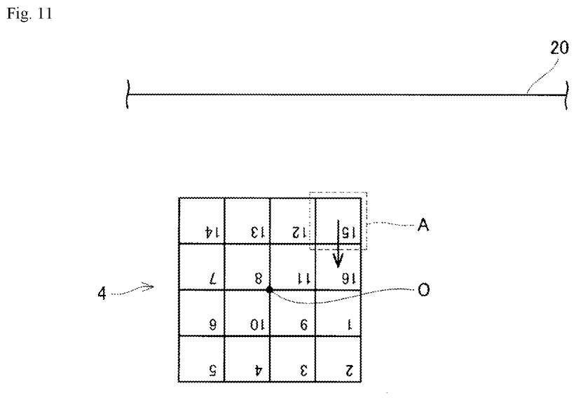

When imaging region 14 is imaged, control device 26 further rotates nozzle 6 counterclockwise by 90 degrees about the axis of nozzle 6. Then, electronic component 4 is rotated about center O and is changed from the state illustrated in FIG. 10 to the state illustrated in FIG. 11. In the example illustrated in FIG. 10, imaging region 14 is located in the first row from the side of board conveyor 20. Therefore, even when electronic component 4 is rotated about center O of electronic component 4 in the state illustrated in FIG. 10, electronic component 4 does not overlap circuit board 2. As illustrated in FIG. 11, after the rotation, imaging region 15 is located in imaging range A. Therefore, control device 26 images imaging region 15 without translating electronic component 4. Thereafter, control device 26 translates nozzle 6 and images imaging region 16. Since imaging region 16 is located in the second row from the side of board conveyor 20 in the state illustrated in FIG. 11, electronic component 4 does not overlap circuit board 2 even when electronic component 4 is translated for the imaging of imaging region 16. In this way, control device 26 images all multiple divided imaging regions of electronic component 4 while combining the translation and the rotation of nozzle 6 at the position at which electronic component 4 does not overlap circuit board 2. Accordingly, the imaging target region of the lower surface (entire lower surface) of electronic component 4 can be imaged without electronic component 4 overlapping circuit board 2.

On the other hand, as illustrated in FIG. 4, when electronic component 4 does not have the size disposed over both the imaging range of imaging device 30 and circuit board 2 (NO in step S14), control device 26 images the imaging target region while translating electronic component 4 (S18). When the imaging target region fits within imaging range A of imaging device 30, control device 26 translates electronic component 4 to a position at which the imaging target region fits within imaging range A, and images the imaging target region. When the imaging target region does not fit within imaging range A of imaging device 30, control device 26 divides the imaging target region and images each imaging region during the translation. Since electronic component 4 does not have the size disposed over both the imaging range of imaging device 30 and circuit board 2, electronic component 4 does not overlap circuit board 2 even when electronic component 4 is translated for the imaging of each of the multiple imaging regions. Therefore, control device 26 can image all the multiple imaging regions by translating electronic component 4. Even in a case where electronic component 4 does not have the size disposed over both the imaging range of imaging device 30 and circuit board 2, control device 26 may image each imaging region by rotating nozzle 6 about the axis of nozzle 6, or may image each imaging region by combining the translation and the rotation.

In the present example, in a case where electronic component 4 has the size disposed over both the imaging range of imaging device 30 and the space above circuit board 2, electronic component 4 is translated and rotated not to overlap circuit board 2. However, the configuration is not limited to this. For example, when electronic component 4 interferes with other electronic component 4 previously mounted on circuit board 2 when electronic component 4 is translated to enter the imaging range of imaging device 30, nozzle 6 (that is, electronic component 4 picked up by nozzle 6) may be translated and rotated not to interfere with other previously mounted electronic component 4. Specifically, in step S12, control device 26 acquires the data of electronic component 4 to be mounted and a mounting position and the dimension in the height direction of other previously mounted electronic component 4. Next, in step S14, control device 26 determines whether electronic component 4 to be mounted may interfere with other previously mounted electronic component 4 when electronic component 4 to be mounted is translated to enter the imaging range of imaging device 30. When electronic component 4 to be mounted does not interfere with other previously mounted electronic component 4 (YES in step S14), control device 26 proceeds to step S16, and in a case where electronic component 4 to be mounted may interfere with other previously mounted electronic component 4 (NO in step S14), control device 26 proceeds to step S18. Even in such a case, when electronic component 4 is imaged by imaging device 30, the interference of electronic component 4 with other previously mounted electronic component 4 can be avoided.

Points to note regarding component mounter 10 described in the example will be described. Component feeder 12 of the example is an example of a “component supply device”, mounting head 16 and head moving device 18 are examples of a “component moving device”, and board conveyor 20 is an example of a “board conveyance device”.

Although specific examples of the technique disclosed in the present description have been described in detail above, the specific examples are merely examples and are not intended to limit the scope of claims. The technique claimed in the scope of claims includes various modifications and alterations which are made to the specific examples that have been described above. In addition, the technical elements described in the present description or the drawings exhibit technical usefulness alone or in various combinations, and are not limited to the combinations described in claims at the time of filing. In addition, the technique described in the present description or the drawings simultaneously achieves multiple purposes, and has technical usefulness with achieving one purpose itself of the multiple purposes.

1. A component mounter for mounting an electronic component on a board, the component mounter comprising:
a board conveyance device configured to convey the board to a work position in the component mounter;
a component supply device configured to supply the electronic component;
a nozzle configured to pick up the electronic component supplied from the component supply device;
a component moving device that is capable of moving the nozzle between the component supply device and the work position and rotating the nozzle about an axis of the nozzle;
an imaging device disposed between the component supply device and the board conveyance device and configured to image the electronic component, which is picked up by the nozzle, from below; and
a control device configured to, in a case where the electronic component picked up by the nozzle has an enough size to be disposed over both the entire imaging range of the imaging device and a space above the board conveyed to the work position, when the electronic component is imaged by the imaging device, cause the component moving device to rotate the nozzle at a position at which the electronic component is not located in the space above the board and cause the imaging device to image the electronic component from below before and after the nozzle is rotated about the axis.

2. The component mounter according to claim 1,
wherein the imaging device is configured to, in a case where the electronic component picked up by the nozzle has an enough size to be disposed over both the entire imaging range of the imaging device and the space above the board conveyed to the work position, image each of multiple imaging regions obtained by dividing an imaging target region of the electronic component,
the control device is configured to cause the component moving device to execute
translation processing of translating the nozzle in a plane parallel to a surface of the board at the position at which the electronic component is not located in the space above the board, and
rotation processing of rotating the nozzle about the axis at the position at which the electronic component is not located in the space above the board, and
the control device is configured to cause the imaging device to image all the multiple imaging regions by combining the translation processing and the rotation processing.

3. A component mounter for mounting an electronic component on a board, the component mounter comprising:
a board conveyance device configured to convey the board to a work position in the component mounter;
a component supply device configured to supply the electronic component;
a nozzle configured to pick up the electronic component supplied from the component supply device;
a component moving device that is capable of moving the nozzle between the component supply device and the work position and rotating the nozzle about an axis of the nozzle;
an imaging device disposed between the component supply device and the board conveyance device and configured to image the electronic component, which is picked up by the nozzle, from below; and
a control device configured to, in a case where the electronic component picked up by the nozzle interferes with an electronic component previously mounted on the board conveyed to the work position when the nozzle is translated in a plane parallel to a surface of the board such that the electronic component picked up by the nozzle is disposed in the entire imaging range of the imaging device, when the electronic component picked up by the nozzle is imaged by the imaging device, cause the component moving device to rotate the nozzle at a position at which the electronic component picked up by the nozzle does not interfere with the previously mounted electronic component and cause the imaging device to image the electronic component, which is picked up by the nozzle, from below before and after the nozzle is rotated about the axis.

4. An imaging method of, when an electronic component supplied from an electronic component supply position is mounted on a board disposed at a work position, imaging the electronic component, which is disposed in an imaging range provided between the electronic component supply position and the board, from below in the imaging range, the imaging method comprising:
a determination step of determining whether the electronic component has an enough size to be disposed over both the entire imaging range and a space above the board; and
an imaging step of imaging the electronic component from below when it is determined in the determination step that the electronic component has an enough size to be disposed over both the entire imaging range and the space above the board, in which the electronic component is rotated at a position at which the electronic component is not located in the space above the board and the electronic component is imaged from below before and after the rotation.

5. The imaging method according to claim 4, further comprising:
a division step of dividing an imaging target region of the electronic component into multiple imaging regions when it is determined in the determination step that the electronic component has an enough size to be disposed over both the entire imaging range and the space above the board disposed at the work position,
wherein the imaging step includes
a translation step of translating the electronic component in a plane parallel to a surface of the board at the position at which the electronic component is not located in the space above the board, and
a rotation step of rotating the electronic component in the plane parallel to the surface of the board at the position at which the electronic component is not located in the space above the board, and
in the imaging step, all the multiple imaging regions are imaged by combining the translation step and the rotation step.
